(19) United States
(12) Patent Application Publication
(10) Pub. No.: US 2012/0133359 A1
(43) Pub. Date: May 31, 2012

(54) MAGNETIC RESONANCE IMAGING APPARATUS AND METHOD

(76) Inventor: Mitsuharu Miyoshi, Tokyo (JP)

(21) Appl. No.: 13/307,689

(22) Filed: Nov. 30, 2011

(30) Foreign Application Priority Data
Nov. 30, 2010 (JP) 2010-267873

(51) Int. Cl. G01R 33/48; G01R 33/28

(52) U.S. Cl. 324/307; 324/318

(57) ABSTRACT

A magnetic resonance imaging apparatus configured to divide a data acquisition region defined in a k_{y}-k_{z} plane into a plurality of regions and repeatedly execute a data acquisition sequence for acquiring echoes disposed in the regions is provided. The apparatus includes a divide unit configured to divide the data acquisition region into the plurality of regions by a plurality of curved lines defined with a point different from an origin point of the k_{y}-k_{z} plane as a reference.

### CROSS REFERENCE TO RELATED APPLICATIONS

This application claims the benefit of Japanese Patent Application No. 2010-267873 filed Nov. 30, 2010, which is hereby incorporated by reference in its entirety.

### BACKGROUND OF THE INVENTION

The present invention relates to a magnetic resonance imaging apparatus and method for repeatedly executing a data acquisition sequence for acquiring echoes.

A three-dimensional (3D) fast spin echo (FSE) method is described as a 3D imaging method in Japanese Unexamined Patent Publication No. 2005-288195.

Also, a multi-shot 3D magnetic resonance imaging (MRI) data view-ordering strategy is described in U.S. Pat. No. 7,649,354.

In a view ordering used in a conventional 3D FSE method, as shown in FIGS. 17-19, a data acquisition region is divided by straight lines extending in the kz direction. So, the echoes identical in echo number in the 3D FSE method are placed in the kz direction. Accordingly, a problem arises in that ringing and blurring are apt to occur in the ky direction.

There is also known 3D steady state free precession (SSFP) in addition to the 3D FSE.

In a view ordering used in a conventional 3D SSFP method, as shown in FIG. 20, a data acquisition region is divided into regions by concentric circles different in radius centered on an origin point C of k-space. The method is accompanied by the problem that since the echo number n of the origin point C of k-space is limited to n=1, contrast cannot be controlled.

It is thus desirable that the ringing and the blurring can be reduced as much as possible, and further, the contrast can be controlled.

### SUMMARY OF THE INVENTION

The embodiments described herein provide a magnetic resonance imaging apparatus which divides a data acquisition region defined in a ky-kz plane into a plurality of regions and repeatedly executes a data acquisition sequence for acquiring echoes disposed in the regions, including a divide unit which divides the data acquisition region into a plurality of regions by a plurality of curved lines defined with a point different from an origin point of the ky-kz plane as a reference.

Dividing the data acquisition region by the plural curved lines enables dispersion of ringing and blurring in both ky and kz directions.

Further advantages of the embodiments described herein will be apparent from the following description of exemplary embodiments as illustrated in the accompanying drawings.

### BRIEF DESCRIPTION OF DRAWINGS

FIG. 1 is a schematic diagram of an exemplary magnetic resonance imaging apparatus.

FIG. 2 is a diagram showing a reference point P (k_{y0}, k_{z0}) set when a data acquisition region R_{acq} is divided.

FIG. 3 is a diagram showing each selected sampling point.

FIG. 4 is an explanatory diagram used when each sampling point to which an echo number n=2 is assigned is selected.

FIG. 5 is an explanatory diagram used when each sampling point to which an echo number n=k is assigned is selected.

FIG. 6 is a diagram showing the manner in which the data acquisition region R_{acq} is divided into a plurality of regions R₁ through Rₙ_{_{—}}ₘₐₓ.

FIG. 7 is an enlarged diagram of the region R₁.

FIG. 8 is an explanatory diagram used when repetition numbers iter=1 to iter_max are assigned.

FIG. 9 is a diagram showing the repetition numbers iter=1 to iter_max assigned for every R₁ to Rₙ_{_{—}}ₘₐₓ of regions.

FIG. 10 is a diagram illustrating the manner of division of the data acquisition region R_{acq} at the time that echo numbers n are assigned to sampling points using a function func_n (k_{y}, k_{z}) of an equation (1B).

FIG. 11 is a diagram showing the manner of division of the data acquisition region R_{acq} at the time that echo numbers n are assigned to sampling points using a function func_n (k_{y}, k_{z}) of an equation (1C).

FIG. 12 is a diagram showing a flow used when a subject is imaged in accordance with view ordering of the present embodiment.

FIG. 13 is a diagram illustrating one example when the data acquisition region R_{acq} is divided by curved lines using another reference point as the reference.

FIG. 14 is a diagram showing one example in which the data acquisition region is divided by lines other than the circle or ellipse.

FIG. 15 is a diagram illustrating one example of a sequence used in a 3D FSE method.

FIG. 16 is a diagram showing a k_{y}-k_{z} plane.

FIGS. 17-19 are schematic diagrams of a data acquisition region divided into regions by straight lines.

FIG. 20 is a schematic diagram of a data acquisition region divided into regions by concentric circles centered on an origin point C.

### DETAILED DESCRIPTION OF THE INVENTION

Although exemplary embodiments will hereinafter be explained in detail, the invention is not limited to or by the particular embodiments described herein.

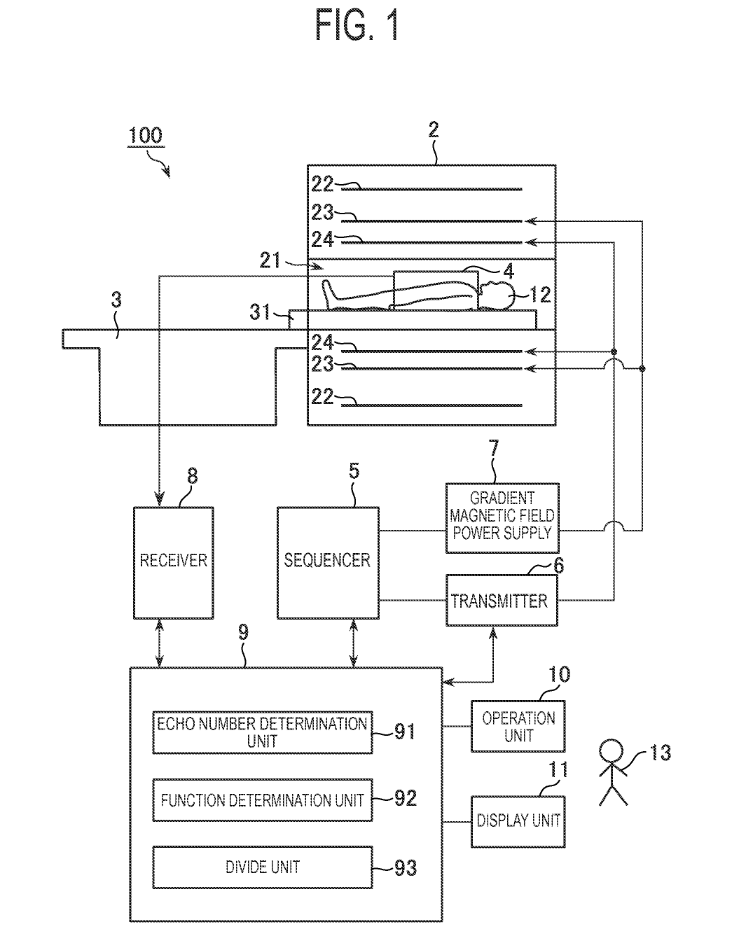

FIG. 1 is a schematic diagram of a magnetic resonance imaging apparatus according to one embodiment.

The magnetic resonance imaging (MRI) apparatus 100 has a magnetic field generator 2, a table 3, and a receiving coil 4.

The magnetic field generator 2 has a bore 21 in which a subject 12 is accommodated, a superconductive coil 22, a gradient coil 23 and a transmitting coil 24. The superconductive coil 22 applies a static magnetic field B0, the gradient coil 23 applies a gradient magnetic field, and the transmitting coil 24 transmits an RF pulse. Incidentally, a permanent magnet may be used instead of the superconductive coil 22.

The table 3 has a cradle 31. The cradle 31 is configured so as to be movable relative to the bore 21. The subject 12 is conveyed to the bore 21 by the cradle 31.

The receiving coil 4 is attached from the abdominal region of the subject 12 to the chest region of the subject. The receiving coil 4 receives magnetic resonance signals from the subject 12.

The MRI apparatus 100 further includes a sequencer 5, a transmitter 6, a gradient magnetic field power supply 7, a receiver 8, a central processing unit 9, an operation unit 10 and a display unit 11.

Under the control of the central processing unit 9, the sequencer 5 transmits information for executing scans of the subject 12 to the transmitter 6 and the gradient magnetic field power supply 7.

The transmitter 6 outputs a drive signal for driving the transmitting coil 24, based on the information transmitted from the sequencer 5.

The gradient magnetic field power supply 7 outputs a drive signal for driving the gradient coil 23, based on the information sent from the sequencer 5.

The receiver 8 signal-processes each magnetic resonance signal received by the receiving coil 4 and transmits it to the central processing unit 9.

The central processing unit 9 controls the operations of respective parts of the MRI apparatus 100 so as to realize various operations of the MRI apparatus 100 such as transmission of information necessary for the sequencer 5 and the display unit 11, reconstruction of an image based on each signal received from the receiver 8, etc. The central processing unit 9 is configured by a computer, for example. The central processing unit 9 has an echo number determination unit 91, a function determination unit 92 and a divide unit 93.

The echo number determination unit 91 determines an echo number to be assigned to an origin point of a k-space.

The function determination unit 92 determines functions func_n (k_{y}, k_{z}) and func_iter (k_{y}, k_{z}) to be described later.

The divide unit 93 divides a data acquisition region of k-space into a plurality of regions.

The central processing unit 9 is one example illustrative of the echo number determination unit 91, the function determination unit 92 and the divide unit 93 and functions as these units by executing a predetermined program.

The operation unit 10 inputs various instructions to the central processing unit 9 in response to the manipulation of an operator 13. The display unit 11 displays various information thereon.

The MRI apparatus 100 is configured as described above.

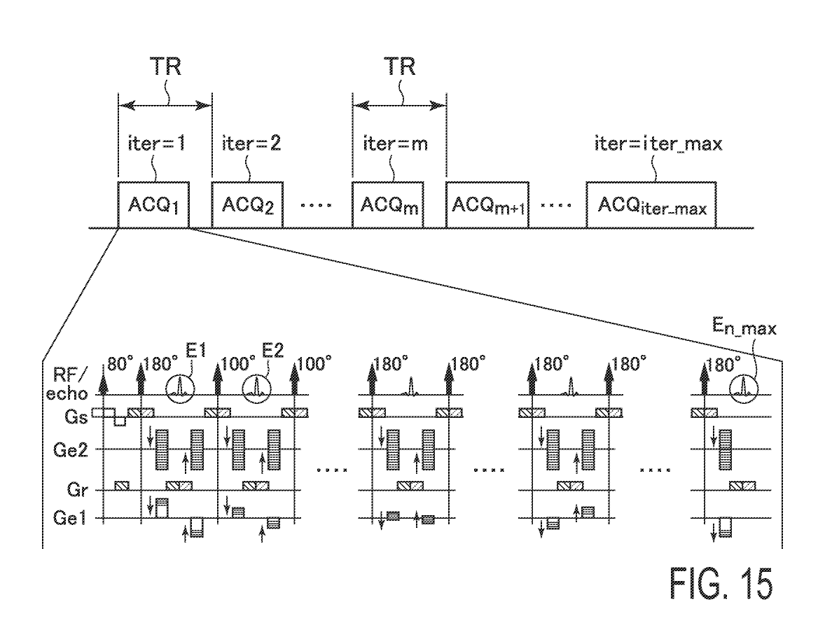

Next, the principle of view ordering of the k-space in the present embodiment when data are acquired using the sequence shown in FIG. 15 will be explained.

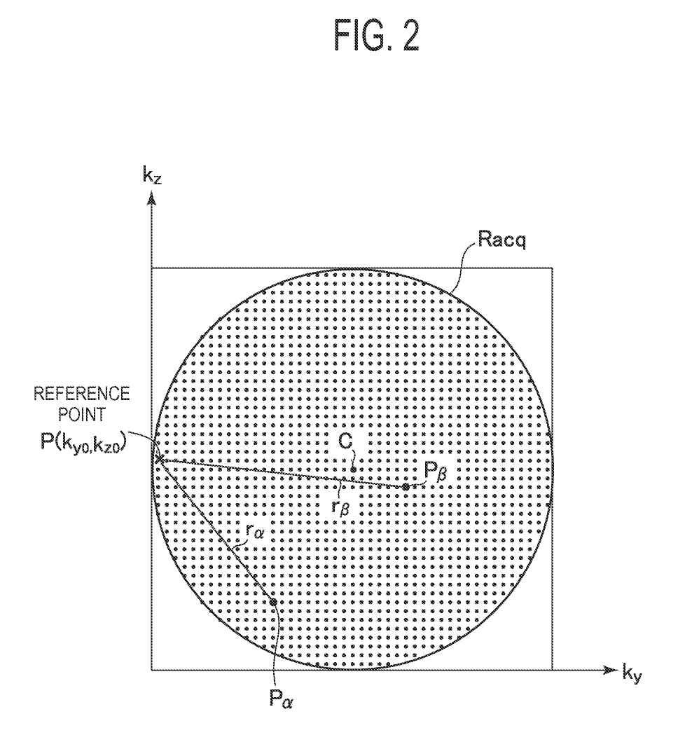

In the present embodiment, the data acquisition region R_{acq} is divided into a plurality of regions. A method for dividing the data acquisition region R_{acq} into the plurality of regions will be explained below while referring to FIGS. 2 through 6.

FIG. 15 is a diagram showing one example of a sequence used in the 3D FSE method.

Incidentally, symbols “iter_max”, “iter”, “n_max” and “n” are used in describing FIG. 15. The meaning of the respective symbols are as follows:

iter_max: the number of times that a data acquisition sequence ACQᵢₜₑᵣ is repeated,

iter: repetition number of data acquisition sequence ACQᵢₜₑᵣ,

n_max: the number of echoes acquired by one data acquisition sequence ACQᵢₜₑᵣ, and

n: echo number.

The data acquisition sequence ACQᵢₜₑᵣ (where iter=1 to iter_max) is repeatedly executed iter_max times. In FIG. 15, data acquisition sequences ACQ₁, ACQ₂, ACQₘ, ACQₘ₊₁, and ACQᵢₜₑᵣ_{_{—}}ₘₐₓ of repetition numbers iter=1, 2, m, m+1 and iter_max are shown. When the repetition number iter_max=500, for example, data acquisition sequences ACQ1 through ACQ500 are executed 500 times.

n_max echoes E₁ through Eₙ_{_{—}}ₘₐₓ are acquired by executing the data acquisition sequence ACQᵢₜₑᵣ once. Echoes E₁ through Eₙ_{_{—}}ₘₐₓ acquired by executing the data acquisition sequence ACQ₁ of the repetition number iter=1 are shown in FIG. 15. Even in the case of the data acquisition sequences ACQᵢₜₑᵣ of other repetition numbers iter, however, echoes E₁ through Eₙ_{_{—}}ₘₐₓ are acquired in like manner.

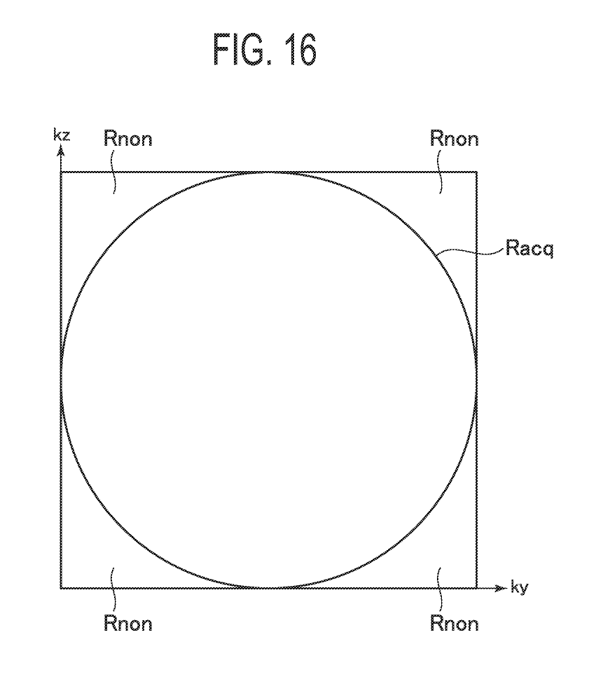

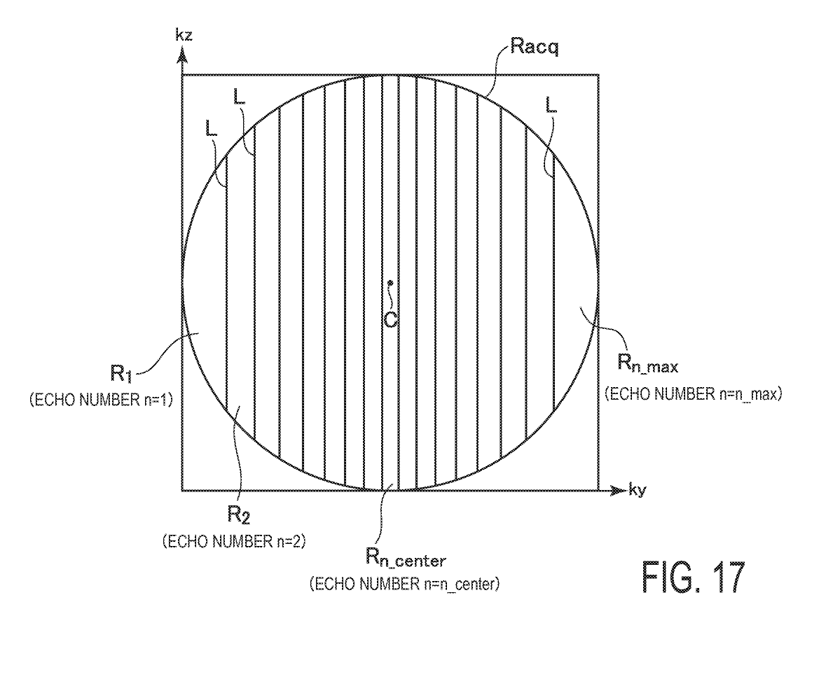

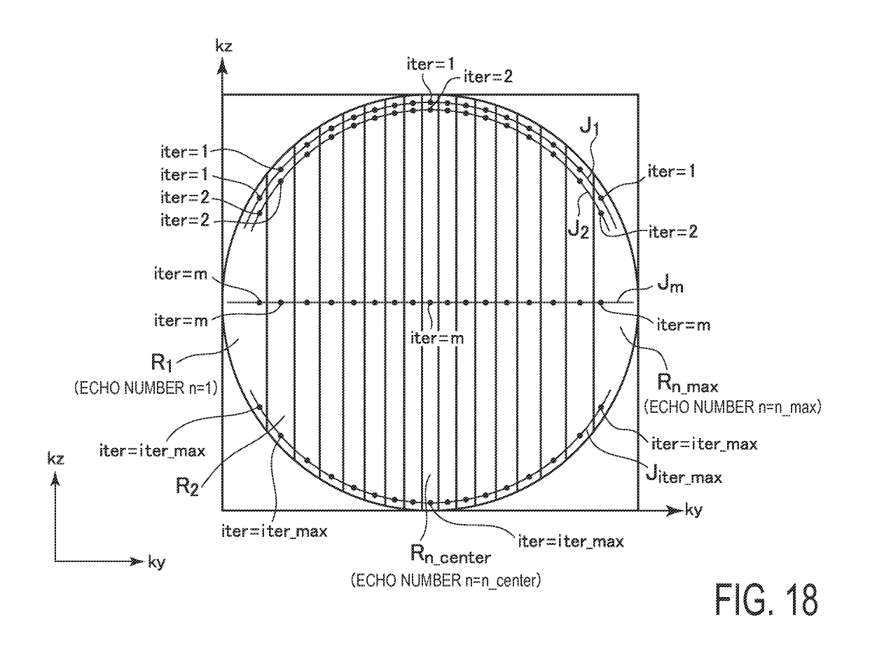

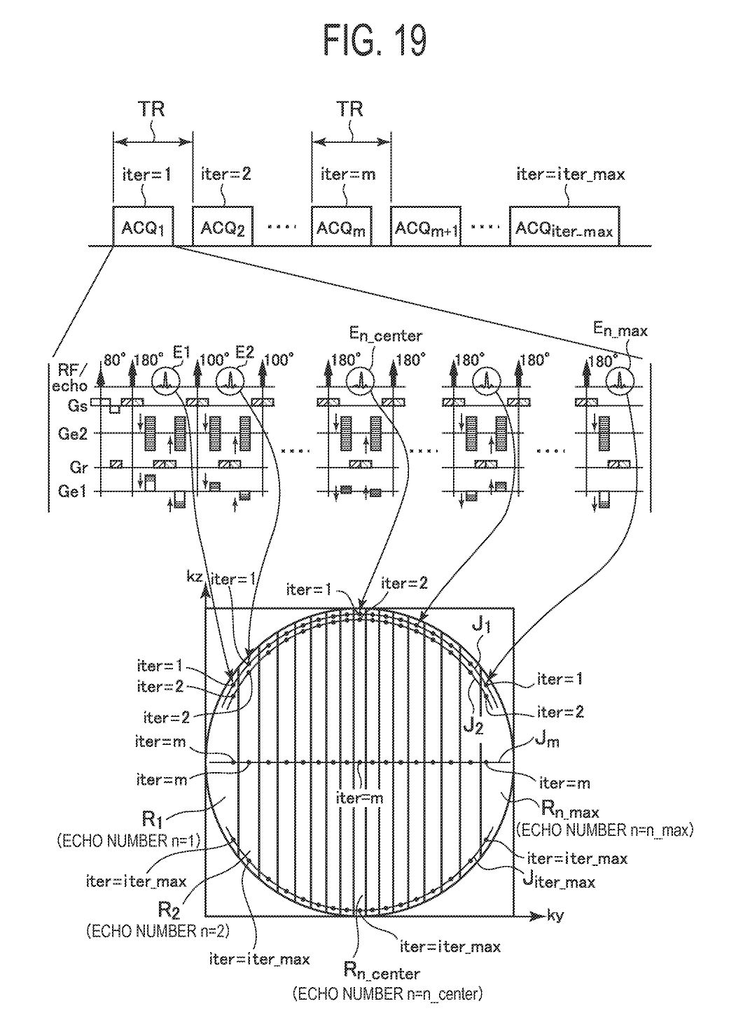

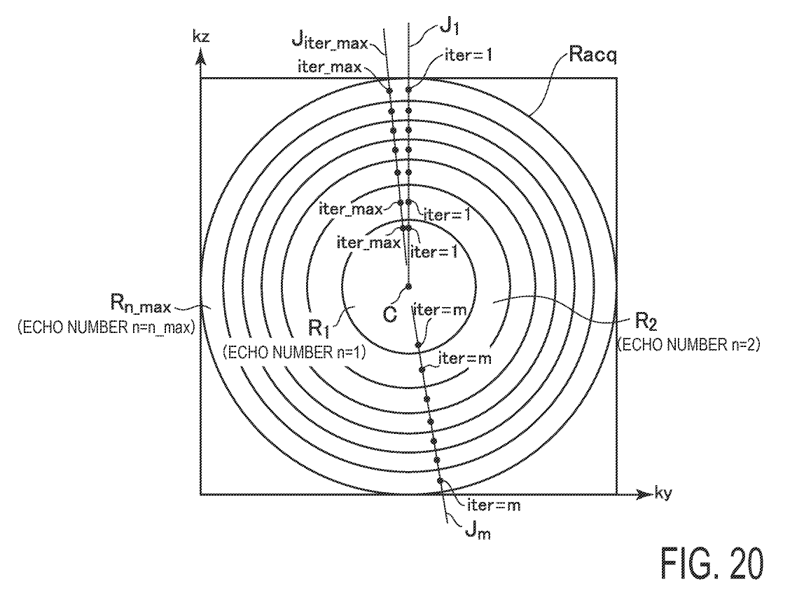

FIG. 16 is a diagram showing a k_{y}-k_{z} plane. A data acquisition region R_{acq} in which the acquisition of data is performed, and data non-acquisition regions Rₙₒₙ in which the acquisition of data is not performed, are defined in the k_{y}-k_{z} plane. The data acquisition region R_{acq} is defined as a region of a circle inscribed in the k_{y}-k_{z} plane. The data acquisition region R_{acq} may however be set as a region having a shape other than the circle. The whole region of the k_{y}-k_{z} plane may be set as the data acquisition region R_{acq}.

FIG. 2 is a diagram showing a reference point P (k_{y0}, k_{z0}( ) used when the data acquisition region R_{acq} is divided. Incidentally, sampling points are respectively indicated by black circles “•” in FIG. 2.

The reference point P (k_{y0}, k_{z0}) is positioned to a position different from the origin point C of k-space. In the present embodiment, echo numbers n=1 to n_max are assigned to the sampling points of the data acquisition region R_{acq} on the basis of the reference point P (k_{y0}, k_{z0}). The assignment of the echo numbers n is performed using a function func_n (k_{y}, k_{z}) expressed in the following equation (1):

$$func\_n ( {k}_{y} , {k}_{z} ) = SQRT \{ \frac{{( {k}_{y} - {k}_{y 0} )}^{2}}{{( {k}_{y\_max} )}^{2}} + \frac{{( {k}_{z} - {k}_{z 0} )}^{2} \cdot {( ratio\_yz )}^{2}}{{( {k}_{z \_max} )}^{2}} \} \qquad ( 1 )$$

where k_{y}_{_{—}}ₘₐₓ: maximum value of k_{y} axis,

k_{z}_{_{—}}ₘₐₓ: maximum value of k_{z} axis,

k_{y0},k_{z0}: coordinate values of reference point, and

ratio_yz: coefficient larger than 0.

The coefficient ratio_yz contained in the equation (1) is an adjustable value. Assume now that the coefficient ratio_yz=1.0. A function func_n (ky, k_{z}) taken when the coefficient ratio_yz=1.0 is expressed in the following equation (1A):

$$func\_n ( {k}_{y} , {k}_{z} ) = SQRT \{ \frac{{( {k}_{y} - {k}_{y 0} )}^{2}}{{( {k}_{y\_max} )}^{2}} + \frac{{( {k}_{z} - {k}_{z 0} )}^{2}}{{( {k}_{z\_max} )}^{2}} \} \qquad ( 1 A )$$

The function func_n (k_{y}, k_{z}) of the equation (1A) indicates the distance between the reference point P (k_{y0}, k_{z0}) and the sampling point P (k_{y}, k_{z}). Accordingly, it means that the smaller the value of the function func_n (k_{y}, k_{z}) of the equation (1A), the closer the sampling point P (k_{y}, k_{z}) is to the reference point P (k_{y0}, k_{z0}). On the other hand, it means that the larger the value of the function func_n (k_{y}, k_{z}) of the equation (1A), the more the sampling point P (k_{y}, k_{z}) is away from the reference point P (k_{y0}, k_{z0}). In FIG. 2, a value r_{α} of a function func_n (k_{y}, k_{z}) of a sampling point P_{α} and a value r_{β} of a function func_n (k_{y}, k_{z}) of a sampling point P_{α} are shown as representatives. It is understood that since r_{α}<r_{β}, the sampling point P_{α} is closer to the reference point P (k_{y0}, k_{z0}) than the sampling point P_{β}.

When the echo numbers n=1 to n_max are assigned, sampling points to which the echo number n=1 is assigned are selected by iter_max from the sampling points of the data acquisition region R_{acq} in order of increasing the value of the function fun_n (k_{y}, k_{z}). Incidentally, iter_max indicates the number of times the data acquisition sequence ACQᵢₜₑᵣ shown in FIG. 15 is repeated. Therefore, when iter_max=500, for example, 500 sampling points to which the echo number n=1 is assigned are selected.

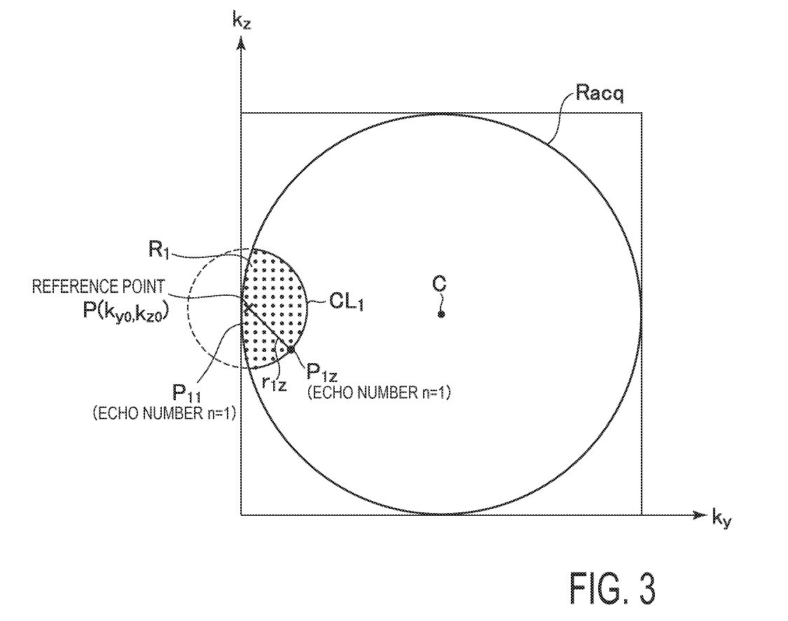

FIG. 3 is a diagram showing selected sampling points.

Incidentally, only the selected sampling points P₁₁ to P_{1z} of iter_max are respectively indicated by the black circles in FIG. 3, and other sampling points are not shown in the drawing. Of the selected sampling points, the two sampling points are designated at symbols “P₁₁” and “P_{1z}” respectively.

Of the values of functions func_n (k_{y}, k_{z}) of the selected sampling points P₁₁ to P_{1z} of iter_max, the maximum value is the value r_{1z} of the function func_n (k_{y}, k_{z}) of the sampling point P_{1z}. Accordingly, a curved line CL₁ of a circle having a radius r_{1z} centered on the reference point P (k_{y0}, k_{z0}) can be used as a curved line for dividing the data acquisition region R_{acq}. A region R₁ for the sampling points P₁₁ through P_{1z} can be determined using the curved line CL₁. The echo number n=1 is assigned to the sampling points P₁₁ through P_{1z} that exist in the region R₁.

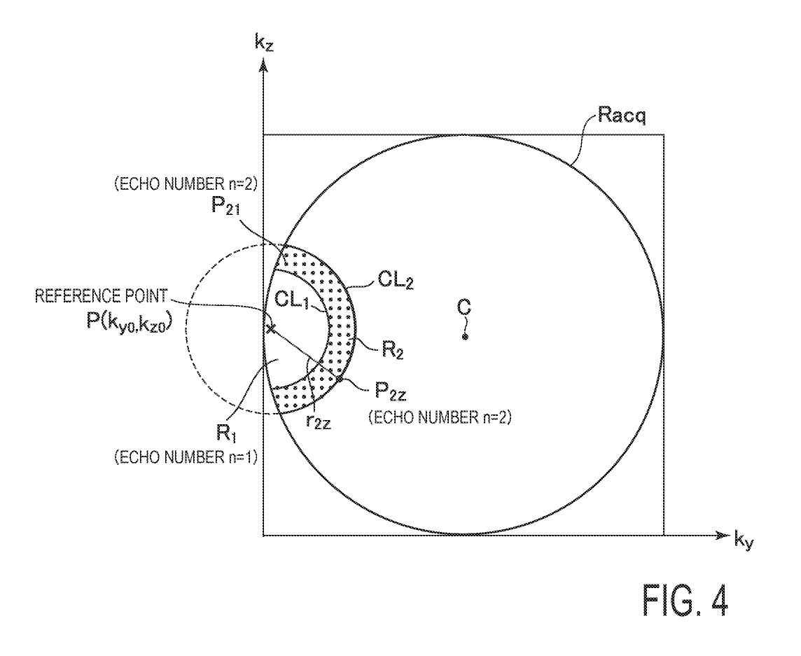

After the echo number n=1 has been assigned to the sampling points P₁₁ through P_{1z}, sampling points assigned the echo number n=2 are next selected (refer to FIG. 4).

FIG. 4 is an explanatory diagram used when the sampling points to which the echo number n=2 is assigned, are selected.

When the sampling points assigned the echo number n=2 are selected, the sampling points are chosen by iter_max in order of increasing the value of the function func_n (k_{y}, k_{z}) except for the sampling points of the region R₁. Assume now that sampling points P₂₁ through P_{2z} are selected as the sampling points each assigned the echo number n=2. Incidentally, in FIG. 4, only the selected sampling points P₂₁ through P_{2z} are respectively indicated by black circles, and other sampling points are not shown in the drawing.

Of the values of the functions func_n (k_{y}, k_{z}) of the selected sampling points P₂₁ through P_{2z}, the maximum value is a value r_{2z} of the function func_n (k_{y}, k_{z}) of the sampling point P_{2z}. Accordingly, a curved line CL₂ of a circle having a radius r_{2z} centered on the reference point P (k_{y0}, k_{z0}) can be used as a curved line for dividing the data acquisition region R_{acq}. A region R₂ for the sampling points P₂₁ through P_{2z} can be determined using the two curved lines CL₁ and CL₂. The echo number n=2 is assigned to the sampling points P₂₁ through P_{2z} that exist in the region R₂.

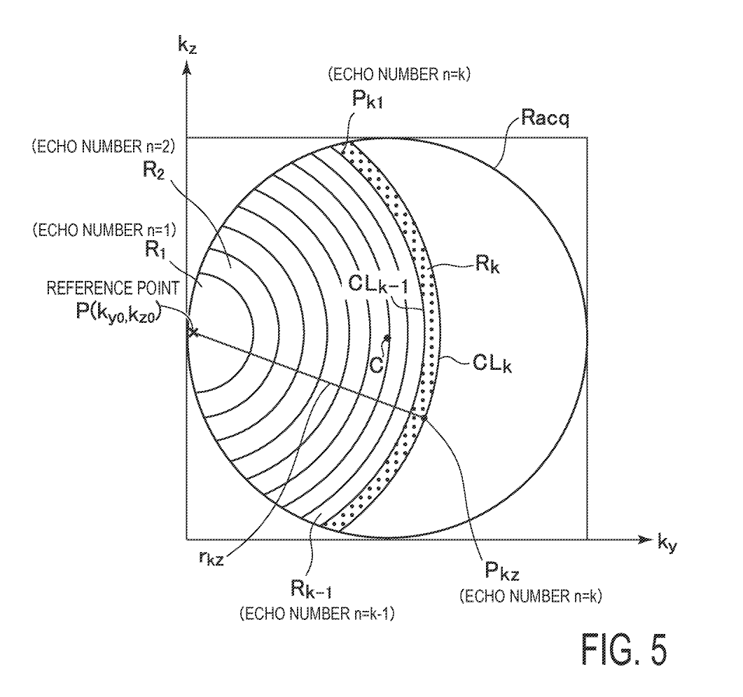

Subsequently, likewise, the echo numbers n are respectively assigned to the remaining sampling points of the data acquisition region R_{acq} while selecting sampling points of iter_max (refer to FIG. 5).

FIG. 5 is an explanatory diagram used when sampling points each assigned the echo number n=k are selected.

When the sampling points to which the echo number n=k is assigned, are selected, the sampling points are selected by inter_max in order of increasing the value of the function func_n (k_{y}, k_{z}) except for sampling points of regions R₁ through Rₖ₋₁. Assume now that sampling points Pₖ₁ through P_{kz} are selected as the sampling points each assigned the echo number n=k. Incidentally, in FIG. 5, only the selected sampling points Pₖ₁ through P_{kz} are respectively indicated by black circles, and other sampling points are not shown in the drawing.

Of the values of the functions func_n (k_{y}, k_{z}) of the selected sampling points Pₖ₁ through P_{kz}, the maximum value is a value r_{kz} of the function func_n (k_{y}, k_{z}) of the sampling point P_{kz}. Accordingly, a curved line CLₖ of a circle having a radius r_{kz} centered on the reference point P (k_{y0}, k_{z0}) can be used as a curved line for dividing the data acquisition region R_{acq}. A region Rₖ for the sampling points Pₖ₁ through P_{kz} can be determined using the two curved lines CLₖ₋₁ and CLₖ. The echo number n=k is assigned to the sampling points Pₖ₁ through P_{kz} that exist in the region Rₖ.

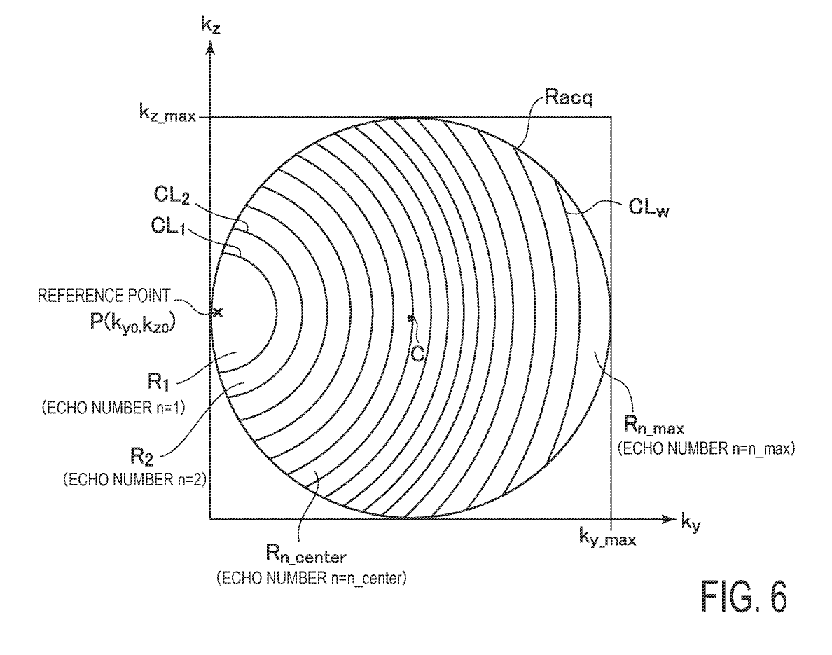

After the assignment of the echo number n=k thereto, the echo number n is assigned even to the remaining sampling points subsequently in like manner in order of increasing the value of the function func_n (k_{y}, k_{z}), while selecting the sampling points of iter_max. Thus, the data acquisition region R_{acq} can be divided into the plural regions R₁ through Rₙ_{_{—}}ₘₐₓ by assigning the echo numbers n=1 to n_max to the sampling points and determining the curved lines for dividing the data acquisition region R_{acq} (refer to FIG. 6).

FIG. 6 is a diagram showing the manner in which the data acquisition region R_{acq} is divided into the plural regions R₁ through Rₙ_{_{—}}ₘₐₓ. Incidentally, the sampling points are omitted in FIG. 6.

As shown in FIG. 6, the data acquisition region R_{acq} is divided into the plural regions R₁ through Rₙ_{_{—}}ₘₐₓ by their corresponding curved lines CL₁ through CL_{w}. The echo numbers n=1 to n_max are assigned to their corresponding sampling points of the regions R₁ through Rₙ_{_{—}}ₘₐₓ. Incidentally, a region containing an origin point C of k-space is expressed in “Rₙ_{_{—}}_{center}”. An echo number n assigned to each sampling point in the region Rₙ_{_{—}}_{center} is expressed in “n_center”. When the data acquisition region R_{acq} is divided by the function func_n (k_{y}, k_{z}) of the equation (1A), the relationship between the echo number n_center and the echo number n_max can be represented by the following equation:

$$n\_center = ( \frac{2}{3} - \frac{\sqrt{3}}{2 π} ) \times n\_max = 0.39 \times n\_max \qquad ( 2 )$$

When the echo number n_max=100, for example, n_center=39. Thus, when the echo number n_max=100, the region Rₙ_{_{—}}_{center} is assigned the echo number n_center=39.

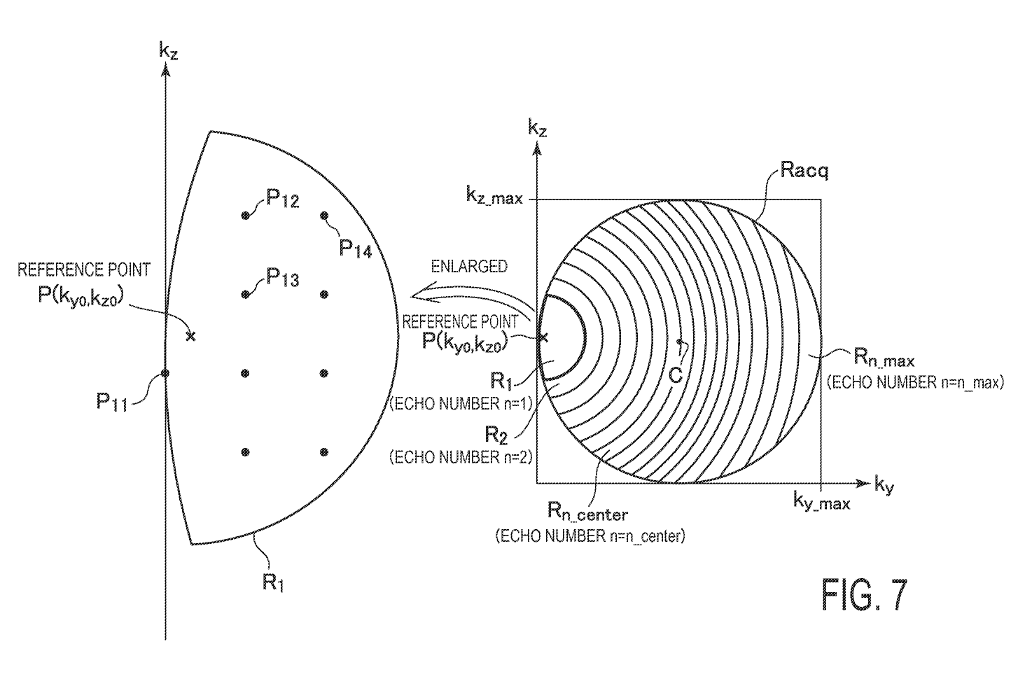

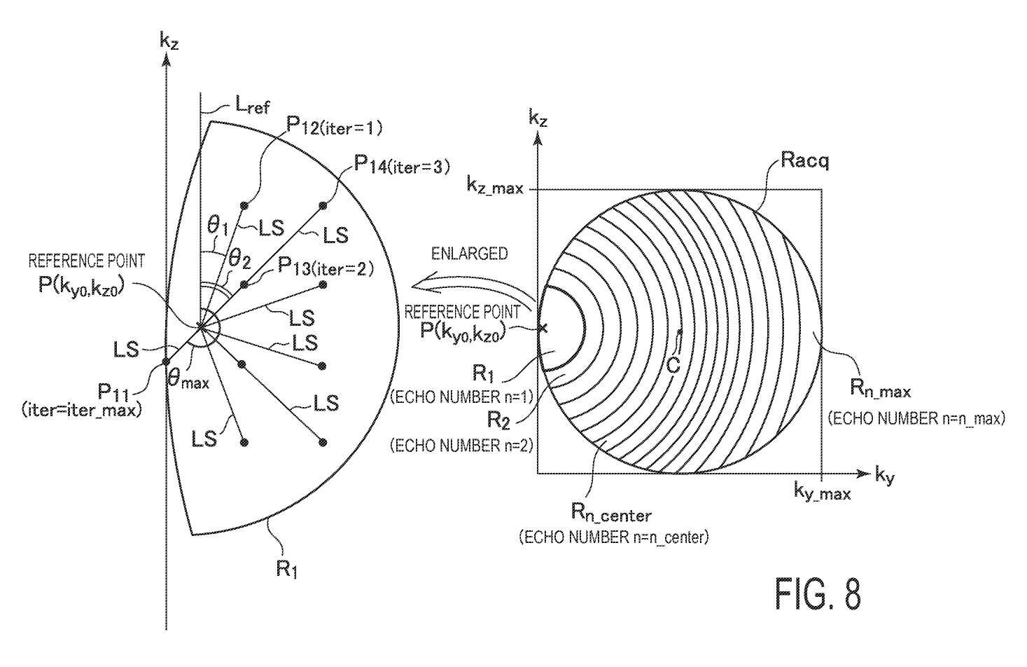

When the data acquisition region R_{acq} is divided as shown in FIG. 6, repletion numbers iter=1 to iter_max are assigned to the sampling points of the regions R₁ through Rₙ_{_{—}}ₘₐₓ, respectively. First, the repetition numbers iter=1 to iter_max are assigned to their corresponding sampling points of the region R₁ (refer to FIGS. 7 and 8).

FIGS. 7 and 8 are explanatory diagrams used when the repetition numbers iter=1 to iter_max are assigned to the sampling points of the region R₁.

FIG. 7 is an enlarged diagram of the region R₁. The sampling points of the region R₁ are indicated by black circles “•” respectively. Incidentally, for convenience of description, only nine sampling points are shown in the region R₁. Of the nine sampling points, the four sampling points are respectively given symbols P₁₁, P₁₂, P₁₃ and P₁₄.

In the present embodiment, the repetition numbers iter=1 to iter_max are assigned to their corresponding sampling points using the following function func_iter (k_{y}, k_{z}):

$$func\_iter ( {k}_{y} , {k}_{z} ) = a tan 2 ( \frac{ratio\_yz ( {k}_{z 0} - {k}_{z} )}{{k}_{z\_max}} , \frac{{k}_{y 0} - {k}_{y}}{{k}_{y\_max}} ) \qquad ( 3 )$$

Assume now that the coefficient ratio_yz contained in the equation (3) is ratio_yz=1.0. The function func_iter (k_{y}, k_{z}) at the time that the coefficient ratio_yz=1.0 is expressed in the following equation (3A):

$$func\_iter ( {k}_{y} , {k}_{z} ) = a tan 2 ( \frac{{k}_{z 0} - {k}_{z}}{{k}_{z\_max}} , \frac{{k}_{y 0} - {k}_{y}}{{k}_{y\_max}} ) \qquad ( 3 A )$$

A method for assigning the repetition numbers iter=1 to iter_max using the function func_iter (k_{y}, k_{z}) of the equation (3A) will be explained below (refer to FIG. 8).

FIG. 8 is an explanatory diagram used when the repetition numbers iter=1 to iter_max are assigned.

The function func_iter (ky, kz) is a function which represents an angle θ of each sampling point relative to the reference point P (ky0, kz0). The angle θ is defined by a reference line Lref and a line segment LS. Here, the reference line Lref indicates a line that extends in a kz-axis direction from the reference point P (ky0, kz0). The line segment LS represents a line which connects the reference point P (ky0, kz0) and each sampling point. In the present embodiment, the angle θ which the reference line Lref forms with each line segment LS is determined using the function func_iter (ky, kz), and the repetition numbers iter are assigned to their corresponding sampling points in order of increasing angle θ. Since the angle θ=θ1 of the sampling point P12 in the sampling points contained in the region R1 is the minimum angle in FIG. 8, for example, the repetition number iter=1 is assigned to the sampling point P12. Since the smallest angle θ after the angle θ1 of the sampling point P12 is given as the angle θ=θ2 of the sampling point P13, the repetition number iter=2 is assigned to the sampling point P13. Incidentally, since the angle θ=θ2 at the sampling point P14 in addition to the sampling point P13, the sampling points identical in the angle θ to each other exist in plural form in FIG. 8. In this case, the small repetition numbers iter are assigned in increasing order of distance from the reference point P (ky0, kz0). Accordingly, the repetition number iter=2 is assigned to the sampling point P13, and the repetition number iter=3 is assigned to the sampling point P14. Subsequently, in like manner, the repetition numbers iter are assigned in increasing order of angle θ, and the repetition number iter=iter_max is assigned to the sampling point P11 at which the angle θ reaches the maximum value θmax. The repetition numbers iter=1 to iter_max are assigned to their corresponding sampling points of the region R1 in this manner.

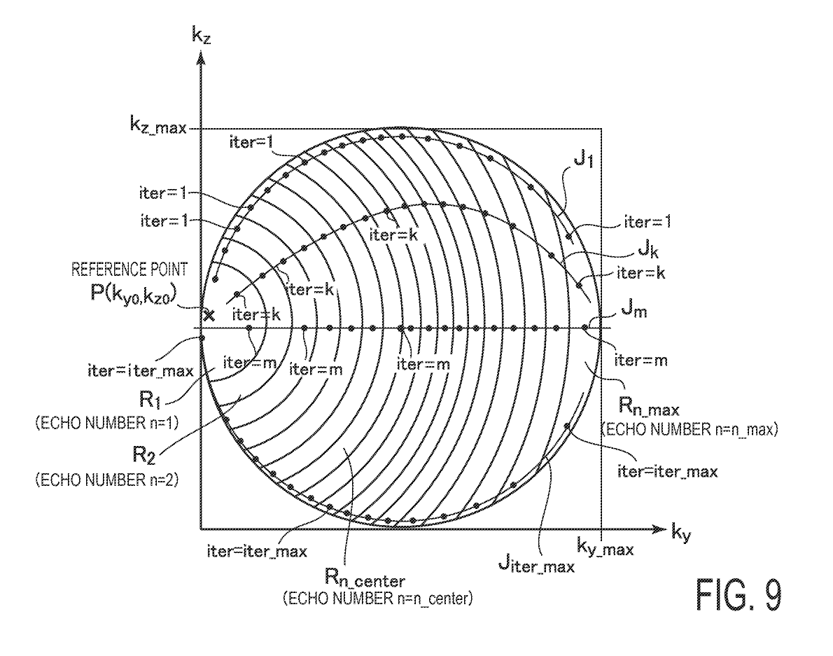

While the above description has been made of the method for assigning the repetition numbers iter=1 to iter_max to the sampling points of the region R₁, the repetition numbers iter are assigned even to their corresponding sampling points of other regions R₂ to Rₙ_{_{—}}ₘₐₓ using the function func_iter (k_{y}, k_{z}) in increasing order of angle θ. Accordingly, the repetition numbers iter=1 to iter_max are assigned for every R₁ to Rₙ_{_{—}}ₘₐₓ of regions (refer to FIG. 9).

FIG. 9 is a diagram showing the repetition numbers iter=1 to iter_max assigned for every R₁ to Rₙ_{_{—}}ₘₐₓ of regions.

In FIG. 9, for convenience of explanation, only the sampling points assigned the repetition numbers iter=1, k, m and iter_max are shown in black circles “•”, but other sampling points are also assigned the repetition numbers iter. In FIG. 9, the sampling points assigned the same repetition number iter are shown on one line. For example, the sampling points assigned the repetition number iter=1 are shown connected by a line J₁. Likewise, the sampling points assigned the repetition number iter=k are shown connected by a line Jₖ, the sampling points assigned the repetition number iter=m are shown connected by Jₘ, and the sampling points given the repetition number iter=iter_max are shown connected by a line Jᵢₜₑᵣ_{_{—}}ₘₐₓ, respectively.

The repetition numbers iter=1 to iter_max are assigned to the sampling points in the respective regions R₁ through Rₙ_{_{—}}ₘₐₓ in this way.

Incidentally, the above description has been made of the case in which the coefficient ratio_yz of the equation (1) is ratio_yz=1.0. The coefficient ratio_yz may however be values other than 1.0. In the case of the coefficient ratio_yz=1.5, for example, the function func_n (ky, kz) is expressed in the following equation (1B). When the coefficient ratio_yz=3.0, the function func_n (ky, kz) is expressed in the following equation (1C).

$$\begin{matrix}func\_n ( {k}_{y} , {k}_{z} ) = SQRT \{ \frac{{{k}_{y} - {k}_{y 0} )}^{2}}{{( {k}_{y\_max} )}^{2}} + \frac{{( {k}_{z} - {k}_{z 0} )}^{2} \cdot {( 1.5 )}^{2}}{{( {k}_{z\_mx} )}^{2}} \} & ( 1 B ) \\ func\_n ( {k}_{y} , {k}_{z} ) = SQRT \{ \frac{{( {k}_{y} - {k}_{y 0} )}^{2}}{{( {k}_{y\_max} )}^{2}} + \frac{{( {k}_{z} - {k}_{z 0} )}^{2} \cdot {( 3 )}^{2}}{{( {k}_{z\_max} )}^{2}} \} & ( 1 C )\end{matrix}$$

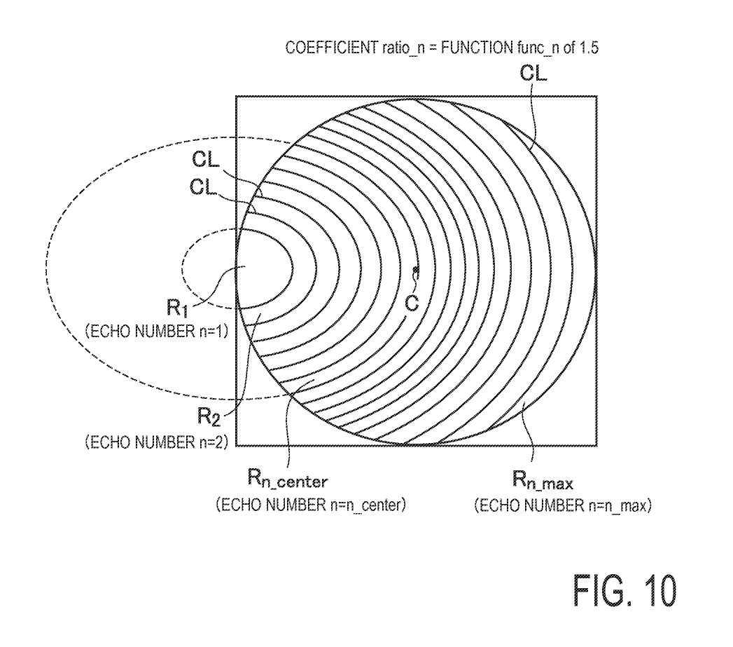

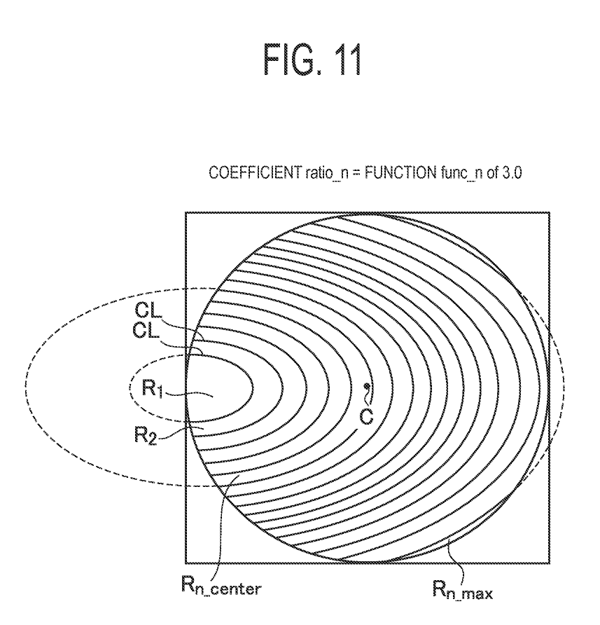

FIG. 10 is a diagram showing the manner of division of the data acquisition region R_{acq} at the time that the echo numbers n are assigned to their corresponding sampling points using the function func_n (k_{y}, k_{z}) of the equation (1B), and FIG. 11 is a diagram showing the manner of division of the data acquisition region R_{acq} at the time that the echo numbers n are assigned to their corresponding sampling points using the function func_n (k_{y}, k_{z}) of the equation (1C).

When the coefficient ratio_yz≠1.0, the data acquisition region R_{acq} is divided into a plurality of regions by elliptical curved lines CL on the basis of the reference point P (k_{y0}, k_{z0}) as shown in FIGS. 10 and 11.

In the case of FIG. 10, the echo number n_center assigned to the region Rₙ_{_{—}}_{center} can be expressed in the following equation (4). In the case of FIG. 11, the echo number n_center assigned to the region Rₙ_{_{—}}_{center} can be expressed in the following equation (5).

n_center=0.30*n_max (4)

n_center=0.16*n_max (5)

In the equation (4), n_center=30 when the echo number n_max=100. For this reason, the echo number n=30 is assigned to the origin point C of k-space. On the other hand, since n_center=16 when the echo number n_max=100 in the equation (5), the echo number n=16 is assigned to the origin point C of k-space in FIG. 11. Thus, in the present embodiment, it is understood that the echo number n_center assigned to the origin point C of k-space can be adjusted according to the coefficient ratio_yz of the function func_c (k_{y}, k_{z}). A method for setting the value of the coefficient ratio_yz of the function func_n (k_{y}, k_{z}) will be explained later.

After the data acquisition region R_{acq} has been divided as shown in FIG. 10 or 11, the repetition numbers iter=1 to iter max are assigned to their corresponding sampling points of the regions R₁ through Rₙ_{_{—}}ₘₐₓ using the function func_inter (k_{y}, k_{z}) of the equation (3). In the case of FIG. 10, the coefficient ratio_yz=1.5. Substituting 1.5 into the ratio_yz of the equation (3) therefore yields the following equation (3B). On the other hand, the coefficient ratio_yz=3.0 in the case of FIG. 11. Substituting 3.0 into the ratio_yz of the equation (3) therefore yields the following equation (3C).

$$\begin{matrix}func\_iter ( {k}_{y} , {k}_{z} ) = a tan 2 ( \frac{1.5 ( {k}_{z 0} - {k}_{z} )}{{k}_{z\_max}} , \frac{{k}_{y 0} - {k}_{y}}{{k}_{y\_max}} ) & ( 3 B ) \\ func\_iter ( {k}_{y} , {k}_{z} ) = a tan 2 ( \frac{3 ( {k}_{z 0} - {k}_{z} )}{{k}_{z\_max}} , \frac{{k}_{y 0} - {k}_{y}}{{k}_{y\_max}} ) & ( 3 C )\end{matrix}$$

Thus, in FIG. 10, the repetition numbers iter=1 to iter_max are assigned using the function func_iter (k_{y}, k_{z}) expressed in the equation (3B). On the other hand, in FIG. 11, the repetition numbers iter=1 to iter_max are assigned using the function func_iter (k_{y}, k_{z}) expressed in the equation (3C).

The view ordering is performed in the above-described manner.

In the present embodiment, the curved lines for dividing the data acquisition region R_{acq} vary not only in a k_{z} direction but also in a k_{y} direction. It is thus possible to disperse ringing and blurring in both k_{y} and k_{z} directions.

A flow used when the subject is imaged in accordance with the view ordering of the present embodiment will next be explained. Incidentally, while a description is made of a flow taken where data are acquired using the sequence of 3D FSE shown in FIG. 15, the embodiments described herein can be applied even to a case in which data are acquired using another 3D sequence such as a sequence of 3D SSFP in addition to the 3D FSE sequence.

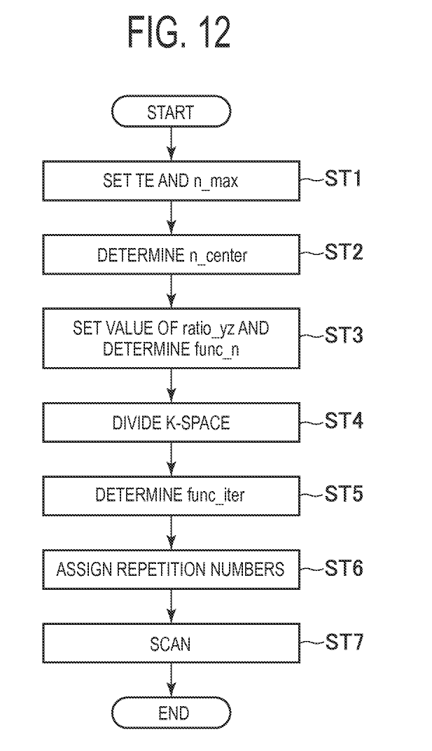

FIG. 12 is a diagram showing a flow used when the subject is imaged in accordance with the view ordering of the present embodiment.

At Step ST1, the operator 13 sets an echo time TE and an echo number n_max of the sequence shown in FIG. 15. Assume now that the operator 13 has set the echo number n_max=100.

At Step ST2, the echo number determination unit 91 (refer to FIG. 1) determines the echo number n=n_center assigned to the origin point C of k-space, based on the echo time TE and the value of the echo number n_max or the like. Now, assume that the echo number n has been set to n_center=39. After the echo number n_center has been determined, the operator 13 proceeds to Step ST3.

At Step ST3, the function determination unit 92 (refer to FIG. 1) first sets the value of the coefficient ratio_yz of the equation (1) in such a manner that the echo number n_center=39 determined at Step ST2 is assigned to the origin point C of k-space. As one example of a method for setting the value of the coefficient ratio_yz, there is a method for creating the relationship of correspondence between the value of the echo number n_max, the value of the echo number n_center, and the value of the coefficient ratio_yz. In the present embodiment, the echo number n_number=100 is set by the operator 13 at Step ST1, and the echo number n_center=39 is set thereby at Step ST2. It is therefore possible to set the value of the coefficient ratio_yz by creating the above relationship of correspondence in advance. Here, assume that the value thereof is set to the coefficient ratio_yz=1.0. The function determination unit 92 substitutes the set coefficient ratio_yz=1.0 into the equation (1). The function func_n (k_{y}, k_{z}) used to divide the data acquisition region is determined by substituting the coefficient ratio_yz=1.0 into the equation (1). When the coefficient ratio_yz=1.0, the determined function func_n (ky, k_{z}) is expressed in the equation (1A). After the determination of the function func_n (ky, k_{z}), the operator 13 proceeds to Step ST4.

At Step ST4, the divide unit 93 (refer to FIG. 1) assigns the echo numbers to their corresponding sampling points of the data acquisition region R_{acq} using the function func_n (k_{y}, k_{z}) determined at Step ST3. Then, the divide unit 93 defines the curved lines CL₁ through CL_{z} to the data acquisition region R_{acq}, based on the assigned echo numbers to divide the data acquisition region into the plural regions R₁ through Rₙ_{_{—}}ₘₐₓ as shown in FIG. 6. After the division thereof, the operator 13 proceeds to Step ST5.

At Step ST5, the function determination unit 92 substitutes the coefficient ratio_yz=1.0 set at Step ST3 into the equation (3). By substituting the coefficient ratio_yz=1.0 into the equation (3), the function func_iter (k_{y}, k_{z}) used to assign repetition numbers to their corresponding sampling points of the regions R₁ through Rₙ_{_{—}}ₘₐₓ is determined When the coefficient ratio_yz=1.0, the determined function func_iter (k_{y}, k_{z}) is expressed in the equation (3A). After the determination of the function func_iter (k_{y}, k_{z}), the operator 13 proceeds to Step ST6.

At Step ST6, the numbers iter are assigned to their corresponding sampling points of the regions R₁ through Rₙ_{_{—}}ₘₐₓ using the function func_iter determined at Step ST5 (refer to FIG. 9). After the assignment of the numbers iter thereto, the operator 13 proceeds to Step ST7, where a scan for acquiring data is executed, and the flow is terminated.

In the present embodiment, the curved lines for dividing the data acquisition region R_{acq} vary not only in the k_{z} direction but also in the k_{y} direction. It is thus possible to disperse ringing and blurring in both k_{y} and k_{z} directions.

The reference point P (k_{y0}, k_{z0}) of the function func_n (k_{y}, k_{z}) deviates from the origin point C of k-space. Thus, the echo number n_center assigned to the origin point C of k-space can be adjusted by simply changing the value of the coefficient ratio_yz contained in the function func_n (k_{y}, k_{z}). It is therefore possible to easily adjust contrast.

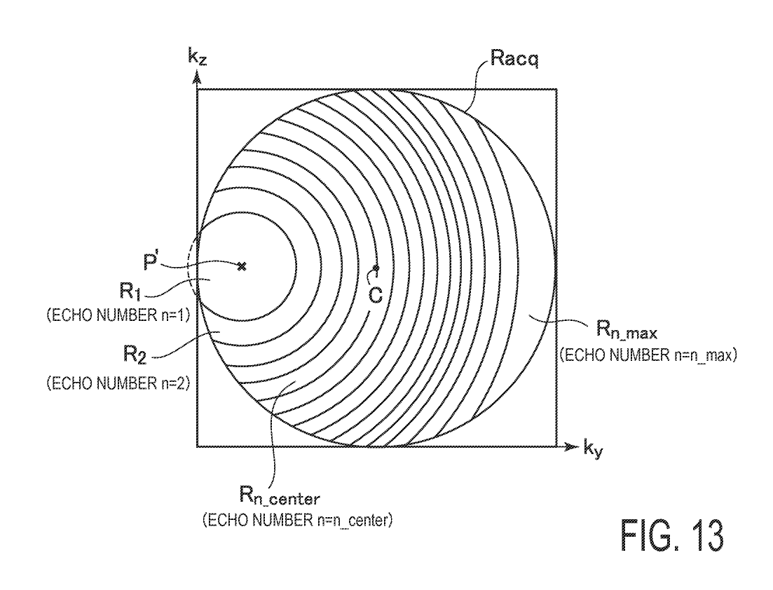

In the present embodiment, the curved lines for dividing the data acquisition region R_{acq} is defined on the basis of the reference point P (k_{y0}, k_{z0}) (refer to FIG. 6). The curved lines may however be defined on the basis of another reference point (refer to FIG. 13).

FIG. 13 is a diagram showing one example in which the data acquisition region R_{acq} is divided by the curved lines based on another reference point.

In FIG. 13, curves lines CL₁ through CL_{w} for dividing the data acquisition region R_{acq} are defined on the basis of a reference point P′. The reference point P′ is set to a position closer to the origin point C of k-space than the reference point P (k_{y0}, k_{z0}) shown in FIG. 6. Thus, the reference point for the curved lines for dividing the data acquisition region R_{acq} can be set to various positions if they are positions different from the origin point C of k-space.

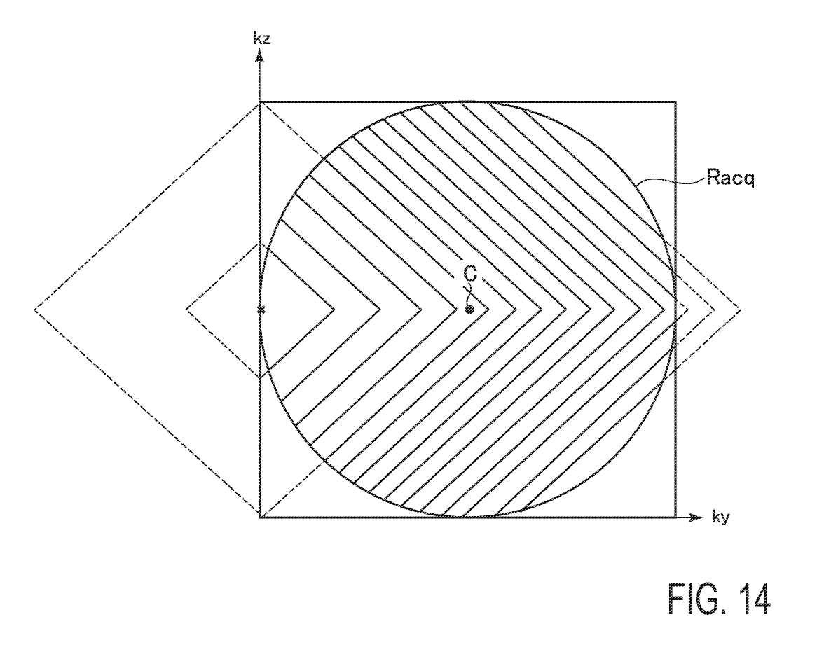

Although the data acquisition region R_{acq} is divided by the circular or elliptical curved lines in the present embodiment, the data acquisition region R_{acq} may be divided by other lines (refer to FIG. 14).

FIG. 14 is a diagram showing one example in which a data acquisition region is divided by lines different from the circular or elliptic curved lines.

FIG. 14 shows a case in which a data acquisition region R_{acq} is divided by rhombus-shaped curved lines based on a reference point P (k_{y0}, k_{z0}). Thus, the curved lines for dividing the data acquisition region R_{acq} may be curved lines like a circle, an ellipse, a hyperbolic curve, a parabola, etc., or may be curved lines formed by a combination of a plurality of straight lines as in the rhombus.

Although the function func_iter (k_{y}, k_{z}) represents the positions of the sampling points at the angles, the positions of the sampling points may be represented using other parameters other than the angles.

Many widely different embodiments of the invention may be configured without departing from the spirit and the scope of the present invention. It should be understood that the present invention is not limited to the specific embodiments described in the specification, except as defined in the appended claims.

1. A magnetic resonance imaging apparatus configured to divide a data acquisition region defined in a k_{y}-k_{z} plane into a plurality of regions and repeatedly execute a data acquisition sequence for acquiring echoes disposed in the regions, comprising:
a divide unit configured to divide the data acquisition region into the plurality of regions by a plurality of curved lines defined with a point different from an origin point of the k_{y}-k_{z} plane as a reference.

2. The magnetic resonance imaging apparatus according to claim 1, comprising a function determination unit configured to determine a first function for assigning an echo number to each of a plurality of sampling points.

3. The magnetic resonance imaging apparatus according to claim 2, comprising an echo number determination unit configured to determine an echo number assigned to the origin point,
wherein the function determination unit is configured to determine the first function, based on a number of echoes acquired by one data acquisition sequence, and the echo number determined by the echo number determination unit.

4. The magnetic resonance imaging apparatus according to claim 2, wherein the divide unit is configured to define the curved lines, based on the echo numbers assigned to the sampling points by the first function.

5. The magnetic resonance imaging apparatus according to claim 3, wherein the divide unit is configured to define the curved lines, based on the echo numbers assigned to the sampling points by the first function.

6. The magnetic resonance imaging apparatus according to claim 2, wherein the function determination unit is configured to determine a second function for assigning repetition numbers of the data acquisition sequence to the sampling points of the plurality of regions.

7. The magnetic resonance imaging apparatus according to claim 3, wherein the function determination unit is configured to determine a second function for assigning repetition numbers of the data acquisition sequence to the sampling points of the plurality of regions.

8. The magnetic resonance imaging apparatus according to claim 4, wherein the function determination unit is configured to determine a second function for assigning repetition numbers of the data acquisition sequence to the sampling points of the plurality of regions.

9. The magnetic resonance imaging apparatus according to claim 5, wherein the function determination unit is configured to determine a second function for assigning repetition numbers of the data acquisition sequence to the sampling points of the plurality of regions.

10. The magnetic resonance imaging apparatus according to claim 6, wherein the second function is a function which represents angles of the sampling points relative to the reference point.

11. The magnetic resonance imaging apparatus according to claim 7, wherein the second function is a function which represents angles of the sampling points relative to the reference point.

12. The magnetic resonance imaging apparatus according to claim 8, wherein the second function is a function which represents angles of the sampling points relative to the reference point.

13. The magnetic resonance imaging apparatus according to claim 9, wherein the second function is a function which represents angles of the sampling points relative to the reference point.

14. The magnetic resonance imaging apparatus according to claim 1, wherein each of the curved lines is at least one of a circle and an ellipse.

15. The magnetic resonance imaging apparatus according to claim 2, wherein each of the curved lines is at least one of a circle and an ellipse.

16. The magnetic resonance imaging apparatus according to claim 3, wherein each of the curved lines is at least one of a circle and an ellipse.

17. The magnetic resonance imaging apparatus according to claim 4, wherein each of the curved lines is at least one of a circle and an ellipse.

18. The magnetic resonance imaging apparatus according to claim 6, wherein each of the curved lines is at least one of a circle and an ellipse.

19. The magnetic resonance imaging apparatus according to claim 10, wherein each of the curved lines is at least one of a circle and an ellipse.

20. A magnetic resonance imaging method comprising the steps of:
dividing a data acquisition region into a plurality of regions by a plurality of curved lines defined with a point different from an origin point of a k_{y}-k_{z} plane as a reference; and
repeatedly executing a data acquisition sequence for acquiring echoes disposed in the plurality of regions.
